(19) United States
(12) Patent Application Publication
(10) Pub. No.: US 2025/0108415 A1
(43) Pub. Date: Apr. 3, 2025

(54) CLEANING APPARATUS FOR WAFER STORAGE CONTAINER

(71) Applicant: SHIBAURA MECHATRONICS CORPORATION, Kanagawa (JP)

(72) Inventors: Junji ISHIHARA, Kanagawa (JP); Hisaaki MIYASAKO, Kanagawa (JP); Yukinobu NISHIBE, Kanagawa (JP)

(21) Appl. No.: 18/897,797

(22) Filed: Sep. 26, 2024

(30) Foreign Application Priority Data
Sep. 29, 2023 (JP) 2023-170839

(51) Int. Cl. B08B 9/28; B65G 47/90; H01L 21/673

(52) U.S. Cl. CPC B08B 9/28; B65G 47/90; B08B 2209/08; H01L 21/6735

(57) ABSTRACT

According to one embodiment of the present disclosure, a wafer storage container cleaning apparatus includes a cleaning chamber that cleans a wafer storage container. The cleaning chamber includes: a chamber that accommodates a shell of the wafer storage container, and capable of being opened and closed by an opening/closing lid via a hinge; a door holder that holds the door; a cleaning nozzle that supplies a cleaning liquid to the shell and the door; a rotation mechanism that rotates the shell and the door; a circular frame that surrounds an outside of the door and has a height that covers a part of the thickness of the door; and an inclined cover that is provided to be inclined such that an end opposite the hinge is the lowest and is higher toward the circular frame, and guides the cleaning liquid supplied to the door and scattered thereon.

### CROSS-REFERENCE TO RELATED APPLICATIONS

This application is based on and claims priority from Japanese Patent Application No. 2023-170839 filed on Sep. 29, 2023 with the Japan Patent Office, the disclosure of which is incorporated herein in its entirety by reference.

### TECHNICAL FIELD

The present disclosure relates to a cleaning apparatus for a wafer storage container.

### BACKGROUND

Cleaning apparatuses for wafer storage containers have been used to perform various processes such as cleaning and drying the wafer storage containers such as front opening unified pods (FOUPs) or front opening shipping boxes (FOSBs) that accommodate semiconductor wafers.

In a wafer storage container cleaning apparatus, the shell of a FOUP is disposed inside a chamber of the cleaning apparatus, and a door of the FOUP is held by a door holder attached to a lid that is arranged to open and close the opening of the chamber. A liquid is then ejected onto the shell and door of the FOUP inside the chamber, respectively, for cleaning, and a gas is blown inside the chamber for drying the shell and the door.

In such an apparatus, after the drying of the shell and the door of the FOUP is completed in the chamber, the lid of the chamber is opened, and the shell and the door of the FOUP are removed from the chamber by a robot. Water droplets generated during the cleaning may remain in the chamber including the lid without being completely dried. In this case, when the lid of the chamber is opened, the water droplets attached to the lid may fall into the chamber and adhere to the shell of the FOUP. Thus, the water droplets adhering to the FOUP after the drying process may cause contamination of the FOUP or contamination inside the wafer storage container cleaning apparatus. When the FOUP becomes contaminated, it must be cleaned again, which reduces the cleaning efficiency. See, for example, Japanese Patent Laid-Open Publication No. 2005-109523.

### SUMMARY

The present disclosure provides a cleaning apparatus for wafer storage containers (hereinafter, “a wafer storage container cleaning apparatus”) capable of efficiently cleaning and drying wafer storage containers.

A wafer storage container cleaning apparatus, according to one embodiment of the present disclosure, includes a cleaning chamber that cleans a wafer storage container including a shell having a storage space connected to an opening and a door detachable from the opening. The cleaning chamber includes: a chamber having a shell accommodating area for accommodating the shell, and a loading/unloading port that is provided in an upper portion and is openable and closable by an opening/closing lid via a hinge; a door holder that is provided on the opening/closing lid and holds the door; a cleaning nozzle that supplies a cleaning liquid to the shell accommodated in the shell accommodating area and to the door held by the door holder; a rotation mechanism that rotates the shell and the door; a circular frame provided in a position that does not interfere with the door rotated by the rotation mechanism, to surround an outside of the door held by the door holder, and having a height that covers a part of the thickness of the door held by the door holder when the opening/closing lid is in a closed state; and an inclined cover that is provided on an opposite side of the opening/closing lid from the hinge across the circular frame when the opening/closing lid is in the closed state, to be inclined such that an end opposite the hinge is the lowest and is higher toward the circular frame, and that guides the cleaning liquid that is supplied from the cleaning nozzle to the door held by the door holder and scattered thereon. An end portion of the inclined cover on a side where the hinge is provided, is provided at a position where the cleaning liquid is guided to a side surface of the circular frame when the opening/closing lid is shifted from the closed state to an open state, and is provided to have a portion overlapping with the circular frame in a side view.

According to an embodiment of the present disclosure, it is possible to provide a wafer storage container cleaning apparatus capable of efficiently cleaning and drying a wafer storage container.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view illustrating an example of a schematic configuration of a wafer storage container cleaning apparatus, according to an embodiment.

FIG. 2 is a perspective view illustrating the internal structure of a cleaning chamber, according to an embodiment.

FIG. 3 is a perspective view of the cleaning chamber, according to an embodiment, when an opening/closing lid is in an open state (when the opening/closing lid is open).

FIG. 4 is a side view illustrating the internal structure of the cleaning chamber, according to the embodiment, when the opening/closing lid of the cleaning chamber is in an open state.

FIG. 5 is a view illustrating an example of the internal structure of the cleaning chamber, according to the embodiment, when the cleaning chamber is being cleaned.

FIGS. 6A to 6C are views for explaining a cleaning position and a standby position of a cleaning nozzle extending in the horizontal direction, and a drying position and a standby position of a drying nozzle extending in the horizontal direction, according to the embodiment.

FIG. 7 is a side view illustrating the internal structure of the cleaning chamber, according to the embodiment, when the opening/closing lid of the cleaning chamber is in an open state.

FIG. 8 is a perspective view of an inclined cover when viewed from below.

FIG. 9 is a side view of the inclined cover, according to the embodiment.

### DESCRIPTION OF EMBODIMENTS

In the following detailed description, reference is made to the accompanying drawing, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, embodiments of a wafer storage container cleaning apparatus disclosed herein are described in detail with reference to the accompanying drawings. The wafer storage container cleaning apparatus disclosed herein is not limited to the following embodiments. In the following embodiments, a wafer storage container to be subjected to various processes such as cleaning and drying is described as a FOUP, but the wafer storage container to be subjected to various processes is not limited thereto. For example, the wafer storage container to be subjected to various processes may be a FOSB.

### Embodiments

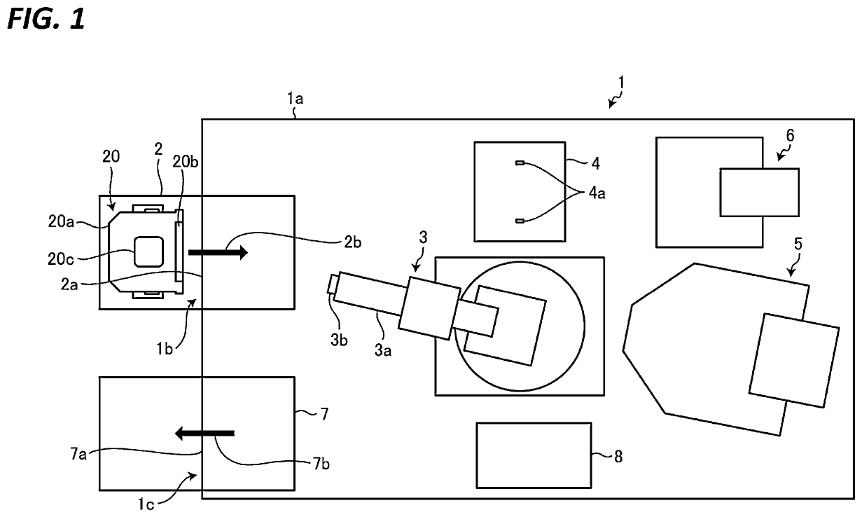

FIG. 1 is a plan view illustrating an example of a schematic configuration of a wafer storage container cleaning apparatus 1, according to an embodiment. The wafer storage container cleaning apparatus 1 is installed, for example, in a factory that manufactures semiconductor wafers, and cleans wafer storage containers and dries the cleaned wafer storage containers.

As illustrated in FIG. 1, the wafer storage container cleaning apparatus 1 includes a load port 2, a robot 3, a lock/unlock stage 4, a cleaning chamber 5, a drying chamber 6, an unload port 7, and a control unit 8.

The robot 3, the lock/unlock stage 4, the cleaning chamber 5, the drying chamber 6, and the control unit 8 are provided inside a casing 1a of the wafer storage container cleaning apparatus 1. Meanwhile, the load port 2 and the unload port 7 are provided across the inside and outside of the casing 1a of the wafer storage container cleaning apparatus 1.

The load port 2 loads the FOUP 20 to be cleaned and dried, which is disposed on the outside of the casing 1a of the load port 2, into the inside of the casing 1a. The FOUP 20 includes a shell 20a, which is the FOUP body, and a door 20b. The shell 20a has an opening (shell opening) and a storage space for storing semiconductor wafers. The storage space is located inside the shell opening and communicates with the shell opening. The door 20b is lockable/unlockable with the shell 20a. The door 20b is attachable to and detachable from the shell opening. The shell 20a is an example of the body. The shell 20a is provided with a flange 20c. The flange 20c is a part that is gripped (held) when the FOUP 20 is transported by an overhead hoist transport (OHT) or a robot 3, and is provided on a surface that intersects with a surface of the shell 20a that has the shell opening.

For example, the FOUP 20 transported by the OHT is disposed on the outside of the casing 1a of the load port 2. For example, as illustrated in FIG. 1, the FOUP 20 is disposed such that the door 20b of the FOUP 20 faces a shutter 2a provided at the opening 1b of the casing 1a. When the FOUP 20 is disposed on the load port 2 in this manner, the shutter 2a is raised. As a result, the FOUP 20 may be loaded into the casing 1a from the opening 1b. That is, the FOUP 20 becomes ready to be loaded into the wafer storage container cleaning apparatus 1. Then, the FOUP 20 is slid in the direction of an arrow 2b by a slide device of the load port 2. As a result, the FOUP 20 is loaded into the casing 1a.

The sliding by the sliding device is described. For example, a pin provided on the sliding device is inserted into a hole provided on a bottom (disposition surface) of the FOUP 20, so that the disposition surface of the FOUP 20 is fixed to the sliding device. In this state, when the sliding device is slid in the direction of the arrow 2b, the FOUP 20 is also slid along with the movement of the sliding device. As a result, the FOUP 20 is disposed on a predetermined portion inside the casing 1a of the load port 2. When the FOUP 20 is thus loaded into the inside of the casing 1a, the shutter 2a is lowered, so that the opening 1b of the casing 1a is closed. The sliding device moves down together with the pin to a position lower than the lower end of the shutter 2a (the disposition surface of the FOUP 20) and returns to the original position outside the casing 1a.

The robot 3 transports the FOUP 20 to each section while gripping the flange 20c of the FOUP 20. The robot 3 includes a robot arm 3a and a robot hand 3b (a gripping unit of the robot 3). The robot 3 transports the FOUP 20 to each section by extending, contracting, and rotating the robot arm 3a while the robot hand 3b is grasping the flange 20c. When the robot 3 transports the door 20b alone that has been separated (unlocked) from the shell 20a, the robot 3 transports the door 20b by gripping both sides of the door 20b.

The lock/unlock stage 4 is a stage on which the FOUP 20 is disposed, and separates (unlocks) the FOUP 20 into a shell 20a and a door 20b, and connects (locks) the shell 20a and the door 20b. For example, the FOUP 20 that has been loaded into the casing 1a is transported to the lock/unlock stage 4 by the robot 3. In this case, the lock/unlock stage 4 separates the FOUP 20 into the shell 20a and the door 20b.

The cleaning chamber 5 is a chamber for cleaning the FOUP 20. For example, the shell 20a and the door 20b are transported separately to the cleaning chamber 5 by the robot 3. Then, the cleaning chamber 5 performs a cleaning process on the FOUP 20 while holding the shell 20a and the door 20b separately. That is, the cleaning chamber 5 cleans the storage space while the shell 20a and the door 20b are separated. For example, the cleaning chamber 5 cleans the FOUP 20 by supplying a cleaning liquid (e.g., deionized water) from a cleaning liquid nozzle onto each of the shell 20a and the door 20b while rotating the shell 20a and the door 20b in a state where the door 20b is held by an opening/closing lid of the cleaning chamber 5 and the shell 20a is held in the chamber portion of the cleaning chamber 5. In the cleaning chamber 5, the FOUP opening of the shell 20a is arranged facing downward, taking into consideration the efficiency of discharging the cleaning liquid.

When cleaning of the FOUP 20 is completed in the cleaning chamber 5, the shell 20a and door 20b are then rotated in the cleaning chamber 5 and dried by blowing dry air thereto from a drying nozzle (air nozzle). The drying in the cleaning chamber 5 is a process for removing the cleaning liquid adhering to the FOUP 20 (temporary drying). When the temporary drying of the FOUP 20 in the cleaning chamber 5 is completed, the robot 3 transports the shell 20a and door 20b in the cleaning chamber 5 separately to the drying chamber 6.

The drying chamber 6 is a device for vacuum drying the FOUP 20 (main drying). When the vacuum drying of the FOUP 20 is completed in the drying chamber 6, the robot 3 transports the shell 20a and the door 20b in the drying chamber 6 separately onto the lock/unlock stage 4. Then, the lock/unlock stage 4 connects the shell 20a and the door 20b.

The unload port 7 unloads the FOUP 20 that has been cleaned and vacuum-dried and that has been disposed by the robot 3 in a portion of the unload port 7 inside the casing 1a, to the outside of the casing 1a.

For example, after the vacuum drying process, the FOUP 20 is transported by the robot 3 and disposed in a portion inside the casing 1a of the unload port 7. When the FOUP 20 is disposed in the unload port 7 in this manner, the shutter 7a provided at the opening 1c of the casing 1a is raised. As a result, the FOUP 20 may be unloaded from the opening 1c to the outside of the casing 1a. That is, the FOUP 20 becomes ready to be unloaded to the outside of the wafer storage container cleaning apparatus 1. Then, the FOUP 20 is slid in the direction of an arrow 7b by the slide device of the unload port 7 (having the same mechanism as the slide device of the load port 2), and the FOUP 20 is unloaded to the outside of the casing 1a. When the FOUP 20 is unloaded to the outside of the casing 1a in this manner, the shutter 7a is lowered, so that the opening 1c of the casing 1a is closed.

The control unit 8 controls the overall operation of the wafer storage container cleaning apparatus 1. For example, the control unit 8 controls the load port 2, the robot 3, the lock/unlock stage 4, the cleaning chamber 5, the drying chamber 6, and the unload port 7, thereby operating the load port 2, the robot 3, the lock/unlock stage 4, the cleaning chamber 5, the drying chamber 6, and the unload port 7 as described above.

For example, the control unit 8 includes a central processing unit (CPU), a read only memory (ROM), a random access memory (RAM), a hard disk drive (HDD), and a communication interface. These are connected via an internal bus.

The CPU executes various processes while using the memory area of the RAM as a temporary storage area for data used in the various processes. The ROM and HDD store programs for executing various processes as described above, and various databases and tables used when executing the various processes. The communication interface is an interface for communicating with the above-mentioned units of the wafer storage container cleaning apparatus 1, and also for communicating with external devices connected to the wafer storage container cleaning apparatus 1 via a network. For example, the communication interface is a network interface card.

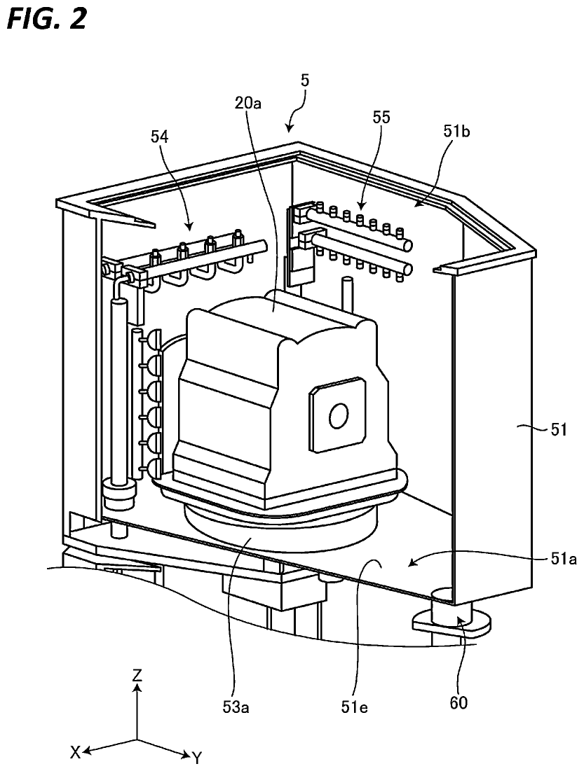

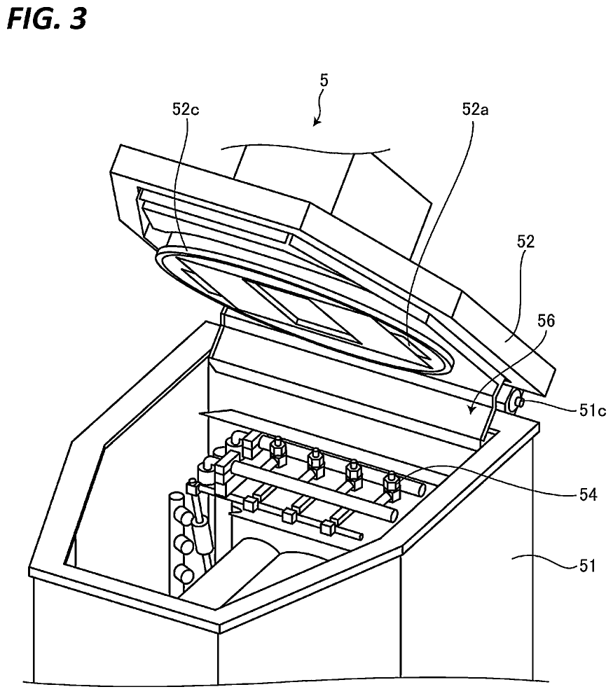

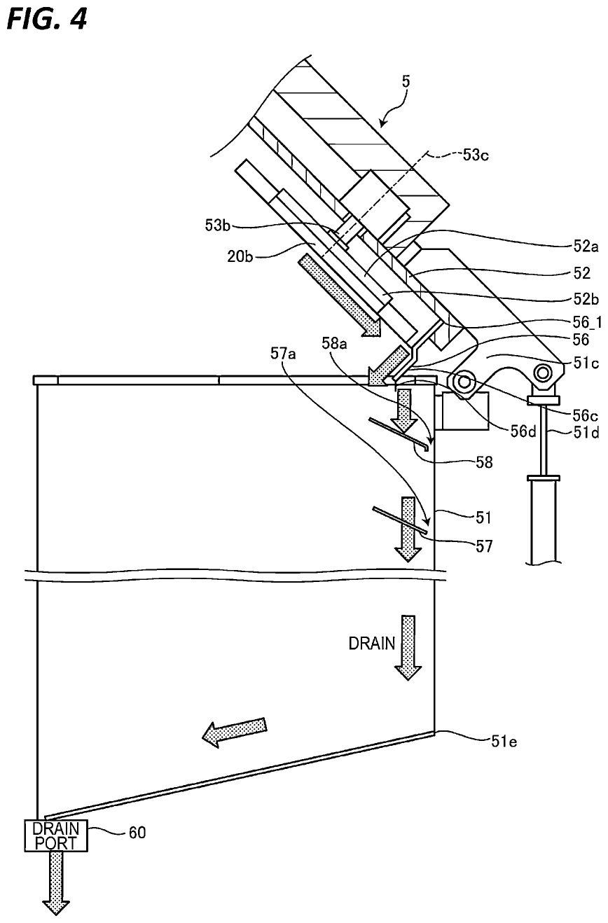

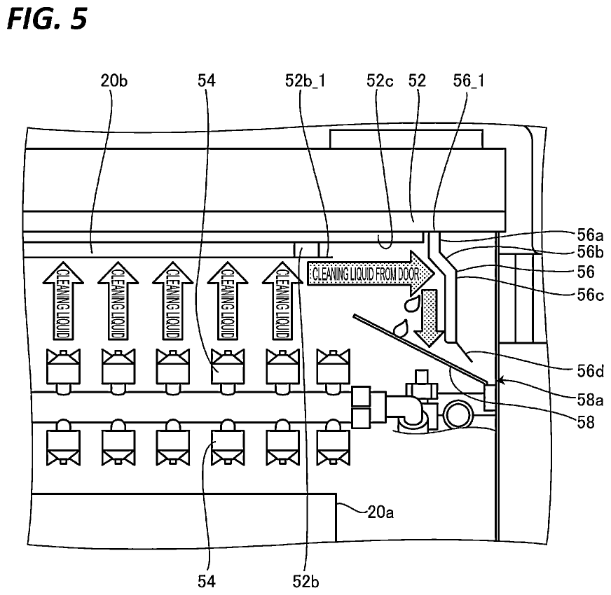

Next, an example of the configuration of the cleaning chamber 5, according to the embodiment is described. FIGS. 2 to 5 are views illustrating an example of the configuration of the cleaning chamber 5, according to the embodiment. FIG. 2 is a perspective view illustrating the internal structure of the cleaning chamber 5, according to the embodiment. FIG. 3 is a perspective view of the cleaning chamber 5, according to the embodiment, when an opening/closing lid 52 is in an open state (when the opening/closing lid 52 is open). FIG. 4 is a side view illustrating the internal structure of the cleaning chamber 5, according to the embodiment, when the opening/closing lid 52 of the cleaning chamber 5 is in an open state. FIG. 5 is a view illustrating an example of the internal structure of the cleaning chamber 5, according to the embodiment, when the cleaning chamber 5 is being cleaned. In each of FIGS. 2 to 5, the components constituting the cleaning chamber 5 are omitted as appropriate, for the sake of convenience. For example, in FIG. 2, the opening/closing lid 52 of the cleaning chamber 5 is omitted. In addition, the X direction, Y direction, and Z direction in FIG. 2 represent three directions perpendicular to each other. The X direction is parallel to the rotation axis of a hinge 51c (to be described below), the Y direction is perpendicular to the X direction in a horizontal plane, and the Z direction is perpendicular to the X direction and the Y direction.

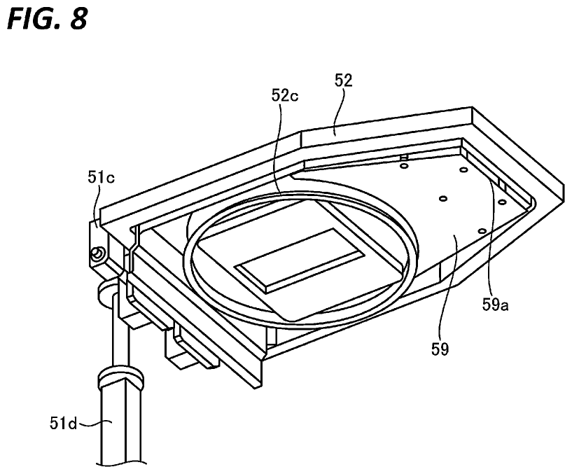

As illustrated in FIGS. 2 to 5, the cleaning chamber 5 includes a chamber 51, an opening/closing lid 52, rotating mechanisms 53a and 53b, a cleaning nozzle 54, a drying nozzle 55, a guide plate 56, a first eaves 57, a second eaves 58, an inclined cover 59 (see, e.g., FIG. 8), and a drain port 60.

The chamber 51 is configured to accommodate the shell 20a and the door 20b when the opening/closing lid 52 is in a closed state (e.g., a state where the opening/closing lid 52 is closed). For example, the chamber 51 has a shell accommodating area 51a and a loading/unloading port 51b as illustrated in FIG. 2. The shell accommodating area 51a is an area (space) capable of accommodating the shell 20a. In addition, the loading/unloading port 51b is an opening of the chamber 51 through which the shell 20a passes when the shell 20a is loaded into or unloaded from the chamber 51 by the robot 3. The shell accommodating area 51a is connected to the loading/unloading port 51b and is located inside the loading/unloading port 51b.

In addition, the chamber 51 is provided with a hinge 51c and an air cylinder 51d (see, e.g., FIG. 4), and the opening/closing lid 52 is attached via the hinge 51c.

The opening/closing lid 52 is attached to the chamber 51 via the hinge 51c. The air cylinder 51d is operated under the control of the control unit 8, thereby operating the hinge 51c, and the opening/closing lid 52 opens and closes with respect to the loading/unloading opening 51b of the chamber 51 in conjunction with the operation of the hinge 51c. The opening/closing lid 52 is in a closed state while the FOUP 20 is being cleaned and dried, and is in an open state when the FOUP 20 is being loaded into the chamber 51 or unloaded from the chamber 51. The opening/closing lid 52 is provided with a door holding portion 52a that holds the door 20b.

As illustrated in FIG. 2, the rotation mechanism 53a is a mechanism that rotates the shell 20a disposed in the shell accommodating area 51a. For example, the rotation mechanism 53a rotates a turntable in the shell accommodating area 51a in a state where the shell 20a is disposed on the turntable, thereby rotating the shell 20a in conjunction with the rotation of the turntable. The rotation mechanism 53a rotates the shell 20a while the shell 20a is being cleaned and while the shell 20a is being dried. The rotation mechanism 53a includes, for example, a motor as a drive source that rotates the turntable.

As illustrated in FIG. 4, the rotation mechanism 53b is a mechanism that rotates the door 20a held by a door holding portion 52a. For example, the rotation mechanism 53b rotates the door 20b by rotating a rotating portion 52b that holds both the door holding portion 52a and the door 20b around a rotation axis 53c that extends perpendicularly to two main surfaces of the door 20b as a rotation center when the door 20b is held by the door holding portion 52a (see, e.g., FIG. 4) as illustrated in FIG. 5. When the opening/closing lid 52 is in the closed state, the two main surfaces of the door 20b are parallel to the horizontal plane. Therefore, when the opening/closing lid 52 is in the closed state, the rotation axis 53c is an axis that extends perpendicularly to the horizontal plane. The rotation mechanism 53b rotates the door 20b while the shell 20a is being cleaned and while the shell 20a is being dried. The rotation mechanism 53b includes, for example, a motor as a drive source that rotates the rotating portion 52b.

The cleaning nozzle 54 has a plurality of types of nozzles each having a different ejection direction (see, e.g., FIG. 2), and cleans the shell 20a and door 20b of the FOUP 20 by supplying (ejecting) a cleaning liquid to the shell 20a accommodated in the shell accommodating area 51a and the door 20b held by the door holding portion 52a. As illustrated in FIG. 2, the cleaning nozzle 54 has two nozzles extending in the horizontal direction (e.g., X direction in the example of FIG. 2) and one nozzle extending in the Z direction. One of the cleaning nozzles 54 extending in the horizontal direction supplies the cleaning liquid toward the door 20b, and the other supplies the cleaning liquid toward the shell 20a. The cleaning nozzle 54 extending in the Z direction supplies the cleaning liquid toward the shell 20a. The cleaning nozzle 54 is connected to a cleaning liquid supply device (not illustrated). The cleaning nozzle 54 supplies the cleaning liquid supplied from the cleaning liquid supply device to the shell 20a and the door 20b.

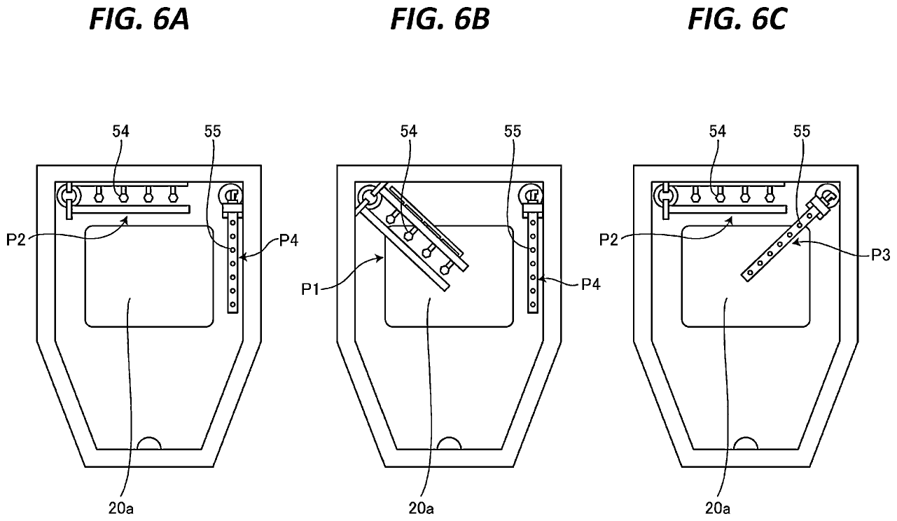

When the cleaning nozzle 54 cleans the FOUP 20, first, a movement mechanism for moving the cleaning nozzle 54 moves the cleaning nozzle 54, which extends horizontally, to a cleaning position P1 (see, e.g., FIG. 6B) at which the cleaning nozzle 54 is able to supply the cleaning liquid to the shell 20a and the door 20b. Then, at the cleaning position P1, the cleaning nozzle 54 ejects the cleaning liquid onto the shell 20a and the door 20b which are being rotated by the rotation mechanisms 53a and 53b. The cleaning nozzle 54 performs such a cleaning process for a predetermined time. Then, after the cleaning process is completed, the movement mechanism moves the cleaning nozzle 54 to a standby position P2 (see, e.g., FIG. 6A). Here, the cleaning position P1 is a position of the cleaning nozzle 54 during the cleaning process, and the standby position P2 is a position for the cleaning nozzle 54 to wait when not performing the cleaning process. The cleaning position P1 is not a single point position, but an area of a certain size. FIG. 2 illustrates the cleaning nozzle 54 at the standby position P2.

The drying nozzle 55 has a plurality of types of nozzles each having a different ejection direction (see, e.g., FIG. 2), and temporarily dries the FOUP 20 (shell 20a and door 20b) by blowing a dry air to the shell 20a accommodated in the shell accommodating area 51a and the door 20b held by the door holding portion 52a. As illustrated in FIG. 2, the drying nozzle 55 has two nozzles extending in the horizontal direction (e.g., Y direction in the example of FIG. 2) and one nozzle extending in the Z direction. One of the drying nozzles 55 extending in the horizontal direction blows the dry air toward the door 20b, and the other blows the dry air toward the shell 20a. The drying nozzle 55 extending in the Z direction blows the dry air toward the shell 20a. The drying nozzle 55 is connected to a dry air supply device (not illustrated). The drying nozzle 55 supplies the dry air supplied from the dry air supply device to the shell 20a and the door 20b.

When the drying nozzle 55 dries the FOUP 20, first, a movement mechanism for moving the drying nozzle 55 moves the drying nozzle 55, which extends horizontally, to a drying position at which the drying nozzle 55 is able to blow the dry air to the shell 20a and the door 20b. Then, at the drying position, the drying nozzle 55 blows the dry air onto the shell 20a and the door 20b which are being rotated by the rotation mechanisms 53a and 53b. The drying nozzle 55 performs such a drying process for a predetermined time. After the drying process is completed, the movement mechanism moves the drying nozzle 55 to the standby position. That is, the drying position is a position of the drying nozzle 55 during the drying process, and the standby position is a position for the drying nozzle 55 that is not performing the drying process to wait. The drying position is an area of a certain size. FIG. 2 illustrates the drying nozzle 55 at the standby position.

FIGS. 6A to 6C are views for explaining the cleaning position and the standby position of the cleaning nozzle 54 extending in the horizontal direction, and the drying position and the standby position of the drying nozzle 55 extending in the horizontal direction, as described above. FIGS. 6A to 6C are top views of the cleaning chamber 5 with the shell 20a stored in the shell accommodating area 51a, but the opening/closing lid 52 of the cleaning chamber 5 is omitted in FIGS. 6A to 6C. FIG. 6A illustrates a state where the cleaning nozzle 54 is located at the standby position P2, and the drying nozzle 55 is located at a standby position P4. When the shell 20a is loaded into the chamber 51, both the cleaning nozzle 54 and the drying nozzle 55 are located at the standby positions as illustrated in FIG. 6A.

FIG. 6B illustrates a state where the cleaning nozzle 54 is located at the cleaning position P1, and the drying nozzle 55 is located at the standby position P4. When the cleaning nozzle 54 supplies the cleaning liquid to the shell 20a and the door 20b to perform cleaning, the cleaning nozzle 54 and the drying nozzle 55 are located at the positions illustrated in FIG. 6B.

FIG. 6C illustrates a state where the cleaning nozzle 54 is located at the standby position P2, and the drying nozzle 55 is located at a drying position P3. When the drying nozzle 55 blows the dry air to the shell 20a and the door 20b to perform drying, the cleaning nozzle 54 and the drying nozzle 55 are located at the positions illustrated in FIG. 6C.

That is, the standby positions of the cleaning nozzle 54 and the drying nozzle 55 are positions where the nozzles do not interfere with the shell 20a when the shell 20a is loaded into and unloaded from the chamber 51. In addition, the cleaning position of the cleaning nozzle 54 and the drying position of the drying nozzle 55 are positions where the cleaning liquid or the dry air is capable of being supplied to at least a part of the shell 20a that is stopped, and where the cleaning liquid or the dry air is supplied to the entire shell 20a as the shell 20a rotates.

As illustrated in FIGS. 4 and 5, the guide plate 56 is provided on the hinge 51c (see, e.g., FIG. 4) side of the opening/closing lid 52, and is a member for guiding the cleaning liquid (e.g., droplets of the cleaning liquid) adhering to the opening/closing lid 52 to the wall surface of the chamber 51. That is, the guide plate 56 guides the cleaning liquid from the opening/closing lid 52 to the wall surface of the chamber 51.

As illustrated in FIG. 5, one end 56_1 of the guide plate 56 is provided on the opening/closing lid 52. The guide plate 56 has a first vertical portion 56a, a first inclined portion 56b, a second vertical portion 56c, and a second inclined portion 56d, which are arranged in this order in a direction extending from the one end 56_1 of the guide plate 56.

As illustrated in FIG. 5, the surface of the first vertical portion 56a facing the door 20b and the surface of the second vertical portion 56c facing the door 20b are perpendicular to the horizontal plane when the opening/closing lid 52 is in the closed state. That is, the first vertical portion 56a and the second vertical portion 56c form surfaces perpendicular to the horizontal plane when the opening/closing lid 52 is in the closed state.

As illustrated in FIG. 5, the first inclined portion 56b is provided at a height position where the cleaning liquid scattered from the door 20b held by the door holding portion 52a and rotated by the rotation mechanism 53b collides when the opening/closing lid 52 is in the closed state. That is, the first inclined portion 56b is provided such that when the opening/closing lid 52 is in the closed state, a position where the cleaning liquid scattered by the centrifugal force from the door 20b collides is included between the upper end and the lower end of the first inclined portion 56b in the Z direction. The first inclined portion 56b has a surface that is inclined such that the upper end of the first inclined portion 56b is located closer to the inside of the chamber 51 (e.g., the side of the rotation mechanism 53b (see, e.g., FIG. 4)) than the lower end of the first inclined portion 56b when the opening/closing lid 52 is in the closed state.

As illustrated in FIG. 5, the first inclined portion 56b receives the cleaning liquid scattered in the centrifugal direction from the door 20b which rotates to receive the cleaning liquid supplied from the cleaning nozzle 54. Since the surface of the first inclined portion 56b facing the door 20b is inclined as described above, it is possible to suppress the cleaning liquid from being reflected toward the shell 20a, even when the first inclined portion 56b receives the cleaning liquid scattered from the door 20b.

In addition, as illustrated in FIG. 5, the first inclined portion 56b may be provided at a height position where the cleaning liquid scattered from an end portion (edge portion) 52b_1 of the rotating portion 52b collides when the opening/closing lid 52 is in the closed state. That is, the first inclined portion 56b is provided such that the height position of the end portion 52b_1 of the rotating portion 52b is included between the upper end and the lower end of the first inclined portion 56b in the height direction when the opening/closing lid 52 is in the closed state. Therefore, the first inclined portion 56b may suppress the cleaning liquid from being reflected toward the shell 20a even when the first inclined portion 56b receives the cleaning liquid scattered from the end portion 52b_1 of the rotating portion 52b, similar to the case of receiving the cleaning liquid scattered from the door 20b.

The second inclined portion 56d is a member for preventing the cleaning liquid adhering to the opening/closing lid 52 and door 20b from dripping onto the shell 20a when the opening/closing lid 52 is opened (e.g., when the opening/closing lid 52 transitions from the closed state to the open state) after the cleaning and the drying are completed in the cleaning chamber 5, and for guiding the cleaning liquid adhering to the opening/closing lid 52 and door 20b to the wall surface of the chamber 51.

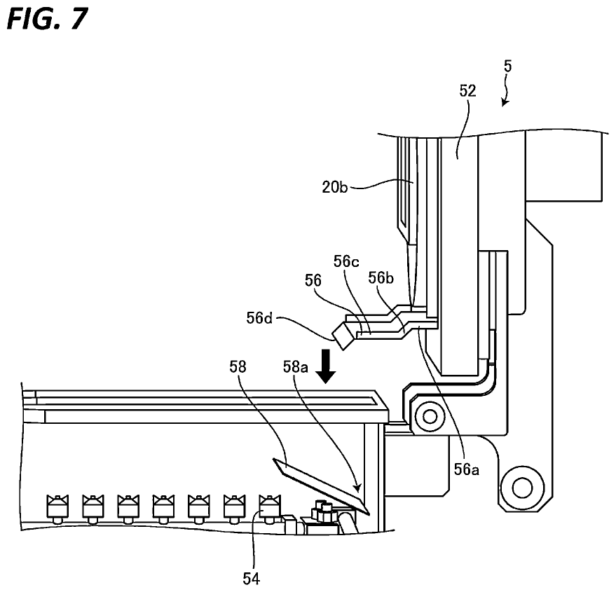

The length of the second inclined portion 56d in the Z direction in the direction in which the second inclined portion 56d is inclined is such that when the opening/closing lid 52 of the chamber 51 is in the closed state as illustrated in FIG. 5, the second inclined portion 56d does not interfere with the first and second eaves 57 and 58 (to be described below), the cleaning nozzle 53, and the drying nozzle 54. FIG. 7 is a side view illustrating the internal structure of the cleaning chamber 5, according to the embodiment, when the opening/closing lid 52 of the cleaning chamber 5 is in the open state. FIG. 7 is a view illustrating a case where the opening/closing lid 52 is opened 90 degrees with respect to a plane including the loading/unloading port 51b of the chamber 51. The length of the second inclined portion 56d in the direction in which the second inclined portion 56d is inclined is also such that when the opening/closing lid 52 is opened 90 degrees as illustrated in FIG. 7, the cleaning liquid adhering to the opening/closing lid 52 and the door 20b does not leak out of the chamber 51, but drips onto the first eaves 57 and the second eaves 58 installed in the chamber 51.

In addition, when the opening/closing lid 52 is opened 45 degrees as illustrated in FIG. 4, the connection portion between the second inclined portion 56d and the second vertical portion 56c is bent toward the opposite side to the shell 20a side such that the cleaning liquid adhering to the opening/closing lid 52 and the door 20b does not drip onto the shell 20a. Specifically, when the opening/closing lid 52 is opened 45 degrees as illustrated in FIG. 4, the surface of the second inclined portion 56d on the door 20b side becomes a surface perpendicular to the horizontal plane. That is, the second inclined portion 56d has a surface perpendicular to the horizontal plane when the opening/closing lid 52 is opened 45 degrees. In addition, a wall for preventing water droplets from dripping may be provided on the portion of the guide plate 56 that is located outside the chamber 51 when the opening/closing lid 52 is opened 90 degrees. That is, the first vertical portion 56a, the first inclined portion 56b, and the second vertical portion 56c may each be provided with a pair of walls that rise vertically from each surface as illustrated in FIG. 7. Even when the opening/closing lid 52 is opened 90 degrees, the second inclined portion 56d, which is positioned to overlap the chamber 51 in a plan view, does not need to have a wall.

Further, the guide plate 56 may be provided on the opening/closing lid 52 such that the end of the second inclined portion 56d opposite to the one end 56_1 (see, e.g., FIG. 5) is located above the first eaves 57 and the second eaves 58, whether the opening/closing lid 52 is in the closed state or the open state. Accordingly, the cleaning liquid may drip from the guide plate 56 onto the first eaves 57 and the second eaves 58, whether the opening/closing lid 52 is in the closed state, the 45-degree open state, or the 90-degree open state.

The first eaves 57 is a member for receiving the cleaning liquid dripping from the guide plate 56, e.g., the cleaning liquid running down the guide plate 56, and guiding the cleaning liquid to the wall surface of the chamber 51. The first eaves 57 is a flat plate-shaped member and is provided below the guide plate 56. One end of the first eaves 57 is provided on the wall surface of the chamber 51. The first eaves 57 is inclined such that the height position becomes higher from one end of the first eaves 57 to the other end. That is, the first eaves 57 is inclined such that the other end is higher than the one end. In addition, a hole 57a through which the cleaning liquid passes is formed between the one end of the first eaves 57 and the wall surface of the chamber 51 (see, e.g., FIG. 4). Therefore, when the first eaves 57 receives the cleaning liquid dripping from the guide plate 56, the cleaning liquid advances on the first eaves 57 toward the hole 57a and passes through the hole 57a.

The second eaves 58 is a member for more reliably guiding the cleaning liquid dripping from the guide plate 56 to the wall surface of the chamber 51. Like the first eaves 57, the second eaves 58 is a member for receiving the cleaning liquid running down the guide plate 56 and guiding the cleaning liquid to the wall surface of the chamber 51. Like the first eaves 57, the second eaves 58 is a flat plate-shaped member and is provided below the guide plate 56. However, when the cleaning nozzle 54 is located at the standby position 54b, the second eaves 58 is provided above the cleaning nozzle 54. Therefore, when not supplying the cleaning liquid, the cleaning nozzle 54 waits at the standby position 54b provided between the second eaves 58 and the first eaves 57.

One end of the second eaves 58 is provided on the wall surface of the chamber 51. The second eaves 58 is inclined such that the height position becomes higher from one end of the second eaves 58 to the other end. That is, the second eaves 58 is inclined such that the other end is higher than the one end. In addition, a hole 58a through which the cleaning liquid passes is formed between the one end of the second eaves 58 and the wall surface of the chamber 51 (see, e.g., FIG. 4). Therefore, when the second eaves 58 receives the cleaning liquid dripping from the guide plate 56, the cleaning liquid advances on the second eaves 58 toward the hole 58a and passes through the hole 58a. It is also possible to provide only the first eaves 57 without providing the second eaves 58. When the second eaves 58 is provided, the cleaning liquid may be guided to the wall surface of the chamber 51 more reliably.

The cleaning liquid that has passed through the hole 57a of the first eaves 57 and the cleaning liquid that has passed through the hole 58a of the second eaves 58 run along the wall of the chamber 51 and reach the bottom surface 51e of the chamber 51 (see, e.g., FIGS. 2 and 4). The cleaning liquid that has reached the bottom surface 51e is discharged (drained) from a drain port 60 (see, e.g., FIGS. 2 and 4) provided on the bottom surface 51e through a pipe (not illustrated) to the outside of the chamber 51. The drain port 60 is provided on the opposite side of the bottom surface 51e from the side where the guide plate 56 is located. The bottom surface 51e is inclined so as to gradually become lower from the side where the guide plate 56 is located to the drain port 60.

Therefore, the cleaning liquid that has reached the bottom surface 51e or the cleaning liquid that has fallen onto the bottom surface 51e flows toward the drain port 60. For this reason, in the embodiment, the cleaning liquid that has fallen onto the bottom surface 51e is discharged without accumulating on the bottom surface 51e.

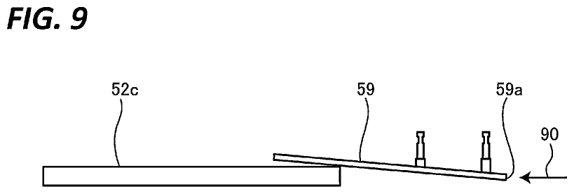

FIGS. 8 and 9 are views illustrating an example of the inclined cover 59, according to the embodiment. FIG. 8 is a perspective view of the inclined cover 59 when viewed from below, and FIG. 9 is a side view of the inclined cover 59, according to the embodiment. In FIG. 9, illustrations other than the inclined cover 59 and a circular frame 52c (to be described below) are omitted.

The circular frame 52c is described. As illustrated in FIGS. 8 and 9, the circular frame 52c is provided on the opening/closing lid 52 so as to surround the outside of the door 20b (see, e.g., FIG. 4) held by the door holding portion 52a (see, e.g., FIG. 4). In addition, the circular frame 52c is provided at a position that does not interferes with the door 20b rotated by the rotation mechanism 53b. The circular frame 52c is provided to prevent the cleaning liquid from entering the inside of the door 20b through a hole (not illustrated) on the side surface of the door 20b. The door holding portion 52a is rotated together with the door 20b by the rotation mechanism 53b, but the circular frame 52c does not rotate.

In addition, as illustrated in FIG. 5, the circular frame 52c has a height sufficient to cover a part of the thickness of the door 20b held by the door holding portion 52a when the opening/closing lid 52 is in the closed state. The surface of the door 20b held by the door holding portion 52a opposite to the surface facing the opening/closing lid 52 is located lower than the circular frame 52c in the height direction (Z direction) of the chamber 51. As a result, the door 20b is thoroughly cleaned with the cleaning liquid from the cleaning nozzle 54.

The inclined cover 59 is a flat member that is inclined such that an end 59a opposite the hinge 16 is lowest when the opening/closing lid 52 is in a closed state and the end 59a becomes higher toward the center of the opening/closing lid 52. For example, when the opening/closing lid 52 is in the closed state, the inclined cover 59 is inclined such that the cleaning liquid adhering to the inclined cover 59 does not drip onto the shell 20a but drips between the shell 20a and the wall surface of the chamber 51.

For example, when the opening/closing lid 52 is in the closed state, the inclined cover 59 receives the cleaning liquid scattered in the centrifugal direction from the door 20b that receives the cleaning liquid supplied from the cleaning nozzle 54 while rotating. As described above, a part of the cleaning liquid scattered from the door 20b heads toward the first inclined portion 56b. At the same time, a part of the cleaning liquid runs down the inclined cover 59. Here, since the inclined cover 59 is inclined as described above, the inclined cover 59 guides the cleaning liquid so that the cleaning liquid attached to the inclined cover 59 does not drip onto the shell 20a but drips between the shell 20a and the wall surface of the chamber 51. The cleaning liquid dripping between the shell 20a and the wall surface of the chamber 51 falls onto the bottom surface 51e of the chamber 51. The cleaning liquid that has fallen onto the bottom surface 51e is discharged from the drain port 60 as described above. Therefore, even when the inclined cover 59 receives the cleaning liquid scattered from the door 20b when the opening/closing lid 52 is in the closed state, the cleaning liquid may be prevented from dripping onto the shell 20a.

In addition, in a side view from the direction indicated by the arrow 90 in FIG. 9, the end of the inclined cover 59 on the central side of the opening/closing lid 52 is provided to have a portion overlapping with the circular frame 52c. In addition, the end of the inclined cover 59 on the central side of the opening/closing lid 52 is provided at a position to guide the cleaning liquid to the side surface of the circular frame 52c when the opening/closing lid 52 is opened (e.g., when the opening/closing lid 52 transitions from the closed state to the open state). Therefore, when the opening/closing lid 52 transitions from the closed state to the open state, the cleaning liquid adhering to the inclined cover 59 passes through the side surface of the circular frame 52c and is guided to the guide plate 56. The cleaning liquid guided to the guide plate 56 passes through the first eaves 57 or the second eaves 58 and is finally discharged from the drain port 60. In this way, the inclined cover 59 guides the cleaning liquid, which has been supplied to the door 20b and scattered thereon, to the side surface of the circular frame 52c when the opening/closing lid 52 transitions from the closed state to the open state. Therefore, the inclined cover 59 may prevent the cleaning liquid from dripping onto the shell 20a even when the opening/closing lid 52 transitions from the closed state to the open state.

As described above, the inclined cover 59 may prevent the cleaning liquid from dripping onto the shell 20a both when the opening/closing lid 52 is in the closed state and when the opening/closing lid 52 transitions from the closed state to the open state. As a result, the cleaning liquid does not adhere to the FOUP 20 that has been dried, so there is no need to clean the FOUP 20 again. Therefore, the wafer storage container cleaning apparatus 1, according to the embodiment, may efficiently clean and dry the FOUP 20.

Next, a procedure of the cleaning process and the drying process performed by the wafer storage container cleaning apparatus 1, according to the present embodiment, is described. First, when the shell 20a and the door 20b are loaded into the chamber 51, the cleaning nozzle 54 moves from the standby position P2 to the cleaning position P1 and performs the cleaning process on the FOUP 20. During the cleaning process, the shell 20a and the door 20b are rotated by the rotation mechanisms 53a and 53b.

When the cleaning process is completed, the cleaning nozzle 54 moves to the standby position P2, and the drying nozzle 55 moves from the standby position P4 to the drying position P3 to perform the drying process on the FOUP 20. While the drying process is being performed by the drying nozzle 55, the cleaning nozzle 54 is located at the standby position P2 above the drainage port 60, and the cleaning liquid remaining in the cleaning nozzle 54 falls, is guided along the first eaves 57 to the wall surface of the chamber 51, and flows to the drainage port 60. Meanwhile, the drying process is being performed by the drying nozzle 55, and the shell 20a and the door 20b are rotated as in the cleaning process. Therefore, the gas from the drying nozzle 55 fills the chamber 51 with centrifugal force. However, the cleaning liquid adhering to the cleaning nozzle 54 flows along the wall surface of the chamber 51 via the first eaves 57 and efficiently flows to the drainage port 60, so that it is possible to suppress the gas from the drying nozzle 55 from scattering into the chamber 51 and re-adhering to the FOUP 20. When the drying process is completed, the drying nozzle 55 moves to the standby position P4.

When the drying process is completed, the opening/closing lid 52 of the chamber 51 is opened. At this time, the cleaning liquid remaining on the opening/closing lid 52 flows along the guide plate 56, the first eaves 57, and the wall surface of the chamber 51, and is discharged from the drain port 60, in the direction indicated by the arrows as illustrated in FIG. 4. In this way, the cleaning liquid remaining on the opening/closing lid 52 is efficiently discharged along the wall surface of the chamber 51, thereby preventing the cleaning liquid from falling onto the shell 20a.

Further, even though the cleaning liquid that falls from the guide plate 56 adheres to the cleaning nozzle 54 located at the standby position 54b, when the next FOUP 20 to be processed is loaded into the cleaning chamber 5, the cleaning nozzle 54 supplies the FOUP 20 with the same cleaning liquid as the cleaning liquid that adhered to the cleaning nozzle 54, so there is no substantial problem.

The wafer storage container cleaning apparatus 1, according to the embodiment, has been described above. The wafer storage container cleaning apparatus 1 has a cleaning chamber 5 for cleaning a FOUP 20. The cleaning chamber 5 includes: a chamber 51 having a shell accommodating area 51a for accommodating a shell 20a, and a loading/unloading port 51b that is provided in an upper portion and is openable and closable by an opening/closing lid 52 via a hinge 51c; a door holding portion 52a that is provided on the opening/closing lid 52 and holds the door 20b; a cleaning nozzle 54 that supplies a cleaning liquid to the shell 20a accommodated in the shell accommodating area 51a and to the door 20b held by the door holding portion 52a; a rotation mechanisms 53a and 53b that rotates the shell 20a and the door 20b; a circular frame 52c that is provided in a position that does not interfere with the door 20b rotated by the rotation mechanism 53b, to surround an outside of the door 20b held by the door holding portion 52a, and having a height that covers a part of the thickness of the door 20b held by the door holding portion 52a when the opening/closing lid 52 is in a closed state; and an inclined cover 59 provided on an opposite side of the opening/closing lid 52 from the hinge 51c across the circular frame 52c when the opening/closing lid 52 is in the closed state, to be inclined such that an end opposite the hinge 51c is the lowest and is higher toward the circular frame 52c, and that guides the cleaning liquid that is supplied from the cleaning nozzle 54 to the door 20b held by the door holding portion 52a and scattered thereon. Also, an end portion of the inclined cover 59 on a side where the hinge 51c is provided is provided at a position where the cleaning liquid is guided to a side surface of the circular frame 52c when the opening/closing lid 52 is shifted from the closed state to an open state, and is provided to have a portion overlapping with the circular frame 52c in a side view.

With this configuration, as described above, when the opening/closing lid 52 of the cleaning chamber 5 is shifted from the closed state to the open state, droplets of the cleaning liquid present on the back of the opening/closing lid 52 flow from the inclined cover 59 along the circular frame 52c to the hinge 51c side. Therefore, according to the wafer storage container cleaning apparatus 1 of the embodiment, it is possible to prevent droplets of the cleaning liquid from adhering to the shell 20a held below the opening/closing lid 52, and therefore the FOUP 20 may be efficiently cleaned and dried.

In addition, a space for a robot 3 to enter the chamber 51 is provided on the front side of the chamber 51 of the cleaning chamber 5 (e.g., the side to which the flange 20c of the shell 20a faces when the shell 20a is loaded into the cleaning chamber 5). This space is necessary for the robot 3 to hold the flange 20c of the shell 20a and dispose the shell 20a in the chamber 51 such that the shell opening of the shell 20a faces downward. Since the chamber 51 has the space, the area of the opening/closing lid 52 must be made large, and the margin other than the portion holding the door 20b becomes large. Therefore, the problem is to efficiently collect the cleaning liquid while preventing the cleaning liquid adhering to the margin from dripping onto the shell 20a. According to the wafer storage container cleaning apparatus 1 of the embodiment, this problem may be solved by having the inclined cover 59 as described above.

In the wafer storage container cleaning apparatus 1, according to this embodiment, a surface of the door 20b held by the door holding portion 52a opposite to a surface facing the opening/closing lid 52 is located lower than the circular frame 52c in the height direction of the chamber 51. Also, a guide plate 56 is provided between the circular frame 52c and the hinge 51c of the opening/closing lid 52 to guide the cleaning liquid from the opening/closing lid 52 to the wall surface of the chamber 51. The guide plate 56 is provided at a height including a height position where the cleaning liquid scattered from the door 20b held by the door holding portion 52a collides when the opening/closing lid 52 is in the closed state, and includes a first inclined portion 56b having a surface inclined such that the upper end is located closer to the inside of the chamber 51 than the lower end.

With this configuration, as described above, the cleaning liquid scattered from the door 20b collides the first inclined portion 56b of the guide plate 56 and is guided to the wall surface of the chamber 51. As a result, it is possible to suppress the cleaning liquid from colliding other portions in the chamber 51 and bouncing back to the shell 20a, thereby preventing the dirt removed from the door 20b from adhering to the shell 20a.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A wafer storage container cleaning apparatus comprising:
a cleaning chamber configured to clean a wafer storage container including a shell having a storage space connected to an opening and a door detachable from the opening,
wherein the cleaning chamber includes:
a chamber having a shell accommodating area for accommodating the shell of the wafer storage container, and a loading/unloading port provided in an upper portion and configured to be opened and closed by an opening/closing lid via a hinge;
a door holder provided on the opening/closing lid and configured to hold the door;
a cleaning nozzle configured to supply a cleaning liquid to the shell accommodated in the shell accommodating area of the chamber and to the door held by the door holder;
a rotation mechanism including a motor configured to rotate the shell and the door;
a circular frame provided in a position that does not interfere with the door rotated by the rotation mechanism, to surround an outside of the door held by the door holder, and having a height that covers a part of the thickness of the door held by the door holder when the opening/closing lid is in a closed state; and
an inclined cover provided on an opposite side of the opening/closing lid from the hinge across the circular frame when the opening/closing lid is in the closed state, to be inclined such that an end opposite the hinge is the lowest and is higher toward the circular frame, and configured to guide the cleaning liquid that is supplied from the cleaning nozzle to the door held by the door holder and scattered thereon, and
wherein an end portion of the inclined cover on a side where the hinge is provided is provided at a position where the cleaning liquid is guided to a side surface of the circular frame when the opening/closing lid is shifted from the closed state to an open state, and is provided to have a portion overlapping with the circular frame in a side view.

2. The wafer storage container cleaning apparatus according to claim 1, wherein a surface of the door held by the door holder opposite a surface facing the opening/closing lid is located lower than the circular frame in a height direction of the chamber,
a guide plate is provided between the circular frame and the hinge of the opening/closing lid to guide the cleaning liquid from the opening/closing lid to a wall surface of the chamber, and
the guide plate is provided at a height position including a height position at which the cleaning liquid scattered from the door held by the door holder collides when the opening/closing lid is in the closed state, and includes a first inclined portion having a surface that is inclined such that an upper end is located closer to an inside of the chamber than a lower end.

3. The wafer storage container cleaning apparatus according to claim 2, wherein one end of the guide plate is provided on the opening/closing lid,
the guide plate includes a first vertical portion, the first inclined portion, a second vertical portion, and a second inclined portion in an order in a direction extending from the one end of the guide plate,
the first vertical portion and the second vertical portion form a surface perpendicular to a horizontal plane when the opening/closing lid is in the closed state, and
the second inclined portion has a surface perpendicular to a horizontal plane when the opening/closing lid is opened 45 degrees.

4. The wafer storage container cleaning apparatus according to claim 2, wherein the cleaning chamber further includes a first eaves having one end on the wall surface of the chamber below the guide plate, and configured to receive the cleaning liquid running down the guide plate and guide the cleaning liquid to the wall surface of the chamber, and
wherein the first eaves is inclined such that a remaining end is higher than the one end, and has a hole through which the cleaning liquid passes, formed between the one end and the wall surface.

5. The wafer storage container cleaning apparatus according to claim 4, wherein the cleaning chamber further includes a second eaves having one end on the wall surface of the chamber between the lower end of the guide plate and the first eaves, a remaining end inclined to be higher than the first end, and a hole through which the cleaning liquid passes, formed between the one end and the wall surface, and
wherein the cleaning nozzle waits at a standby position provided between the second eaves and the first eaves when the cleaning liquid is not supplied.
